(19) United States
(12) Patent Application Publication
(10) Pub. No.: US 2026/0173855 A1
(43) Pub. Date: Jun. 18, 2026

(54) INTERCONNECT STRUCTURE, ELECTRONIC DEVICE INCLUDING THE SAME, AND ELECTRONIC APPARATUS INCLUDING THE SAME

(71) Applicants: SAMSUNG ELECTRONICS CO., LTD., Suwon-si (KR); AJOU UNIVERSITY INDUSTRY-ACADEMIC COOPERATION FOUNDATION, Suwon-si (KR)

(72) Inventors: GIYOUNG JO, Suwon-si (KR); Sang Woon Lee, Suwon-si (KR); Keun Wook SHIN, Suwon-si (KR); JEONGYUB LEE, Suwon-si (KR); Ye Bin Lim, Suwon-si (KR); Juyoung SUNG, Suwon-si (KR); Sanghyeok Lee, Suwon-si (KR)

(21) Appl. No.: 19/414,837

(22) Filed: Dec. 10, 2025

(30) Foreign Application Priority Data
Dec. 12, 2024 (KR) 10-2024-0185164

(51) Int. Cl. H10W 20/44; H10W 20/41

(52) U.S. Cl. CPC H10W 20/4424; H10W 20/435; H10W 20/4446

(57) ABSTRACT

An interconnect structure and an electronic device including the interconnect structure. The interconnect structure includes a substrate, a metal layer on the substrate, and a capping layer in contact with the metal layer and including a nickel-cobalt alloy. The nickel-cobalt alloy has a hexagonal crystal structure (HCP). An electronic device includes a plurality of components. The plurality of components includes a transistor, a capacitor, a diode, a resistor, or a combination thereof, and an interconnect structure disposed at a connection portion between the plurality of components or at a connection portion within each component.

### CROSS-REFERENCE TO RELATED APPLICATION

This application claims priority under 35 U.S.C. § 119 to Korean Patent Application No. 10-2024-0185164 filed with the Korean Intellectual Property Office on Dec. 12, 2024, and all the benefits accruing therefrom under 35 U.S.C. § 119, the disclosure of which in its entirety is incorporated herein by reference.

### BACKGROUND

### 1. Field

The present disclosure relates to an interconnect structure, an electronic device including the interconnect structure, and an electronic apparatus including the interconnect structure.

### 2. Description of the Related Art

In order to provide high-density, high-performance semiconductor devices, efforts are continuing to reduce the line width or thickness of metal wiring. By reducing the line width or decreasing the thickness of metal wiring, the number of semiconductor chips integrated per wafer may be increased. Additionally, when the thickness of the metal wiring is decreased, the capacitance of the line may be reduced, and thus the speed of the signal passing through the wiring may be increased.

However, as the line width or thickness of the metal wiring decreases, the resistance increases rapidly, and thus reducing the resistance of the metal wiring becomes more important than any other factor. Current wiring technology is approaching a physical limit where resistivity increases significantly as line widths are significantly reduced.

Additionally, since deterioration may occur due to oxidation occurring at the metal/oxide interface or exposed metal surface, a technology is needed to reduce the resistance of the wiring structure while preventing metal oxidation.

### SUMMARY

An embodiment provides an interconnect structure capable of reducing or preventing oxidation of metal wiring while reducing an increase in resistance due to a decrease in line width or thickness of the metal wiring.

Another embodiment provides an electronic device including the interconnect structure.

Another embodiment provides an electronic apparatus including the interconnect structure.

According to an embodiment, an interconnect structure includes a substrate, a metal layer disposed on the substrate, and a capping layer in contact with the metal layer and including a nickel-cobalt alloy, wherein the nickel-cobalt alloy has a hexagonal crystal structure (HCP).

The capping layer may be disposed on an upper surface of the metal layer.

The metal layer may include a metal, a metal alloy, or a combination thereof.

The metal may include a transition metal, a Group 3A (Group 13) metal, or a combination thereof.

The metal layer may include one of copper (Cu), ruthenium (Ru), aluminum (Al), cobalt (Co), tungsten (W), molybdenum (Mo), titanium (Ti), tantalum (Ta), nickel (Ni), platinum (Pt), chromium (Cr), rhodium (Rh), iridium (Ir), palladium (Pd), or osmium (Os), an alloy thereof, or a combination thereof.

The nickel-cobalt alloy may include a compound represented by Ni₁₋ₓCoₓ, wherein 0<x<1.

In the nickel-cobalt alloy, x may be in a range of about 0.5 to about 0.99, for example, about 0.6 to about 0.95.

The nickel-cobalt alloy may further include ruthenium (Ru), hafnium (Hf), zirconium (Zr), gadolinium (Gd), niobium (Nb), vanadium (V), or a combination thereof.

A lattice mismatching ratio of a metal, a metal alloy, or a combination thereof of the metal layer and the nickel-cobalt alloy of the capping layer may be less than or equal to about 5%.

The capping layer includes a plurality of layers, a first layer in contact with the metal layer, and a second layer formed on the first layer, and a cobalt content of the nickel-cobalt alloy of the first layer may be higher than a cobalt content of the nickel-cobalt alloy of the second layer.

A difference between the cobalt content of the nickel-cobalt alloy of the first layer and the cobalt content of the nickel-cobalt alloy of the second layer may be greater than or equal to about 10 atomic percentage (at %).

The capping layer may have a thickness of less than or equal to about 10 nanometers (nm).

The substrate may include a dielectric layer having a trench structure, and the interconnect structure includes the metal layer filling an internal portion of the trench structure, and the capping layer on the metal layer.

The trench structure may have a width of less than or equal to about 10 nm and an aspect ratio of greater than or equal to about 3.

The nickel-cobalt alloy may have a cohesive energy of greater than or equal to about 4.5 electronVolts per atom (eV/atom).

A barrier layer may further be included on at least one surface of the internal portion of the trench structure.

The barrier layer may include a metal, a metal alloy, a metal oxide, a metal nitride, or a combination thereof.

The metal of the barrier layer may be magnesium (Mg), aluminum (Al), scandium (Sc), titanium (Ti), vanadium (V), chromium (Cr), manganese (Mn), nickel (Ni), zinc (Zn), gallium (Ga), zirconium (Zr), niobium (Nb), molybdenum (Mo), lead (Pd), silver (Ag), cadmium (Cd), indium (In), tin (Sn), lanthanum (La), hafnium (Hf), tantalum (Ta), tungsten (W), iridium (Ir), platinum (Pt), gold (Au), bismuth (Bi), cobalt (Co), ruthenium (Ru), or a combination thereof. The metal alloy of the barrier layer may include ruthenium-tantalum alloy (RuTa), iridium-tantalum alloy (IrTa), and the like.

The metal oxide of the barrier layer may be a compound represented by Chemical Formula 1:

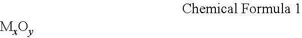

wherein in Chemical Formula 1,
M may be at least one of Mn, Al, Ti, Zr, Hf, Mg, Si, Ge, Y, Lu, La, Ta, and Sr, wherein 0<x≤2, and 0<y≤3.

Examples of the metal oxide may include MnO, AlO_{z}, wherein 0<z≤3/2, TaO_{z}, wherein 0<z≤5/2, TiO₂, ZrO₂, HfO₂, MgO, SiO₂, GeO₂, Y₂O₃, Lu₂O₃, La₂O₃, SrO, and the like.

The metal nitride of the barrier layer may include tantalum nitride (TaN), titanium nitride (TiN), ruthenium nitride (RuN), tungsten nitride (WN), aluminum nitride (AlN), Iridium-Tantalum nitride (IrTaN), titanium silicon nitride (TiSiN), and the like.

A multi-layer structure in which a metal layer and a capping layer are stacked on the substrate, and empty spaces may be present on both sides of the multi-layer structure.

Another embodiment provides a method for manufacturing an interconnect structure, which includes: forming a metal layer on a substrate, depositing a nickel-cobalt alloy on the metal layer to form a capping layer, wherein the nickel-cobalt alloy has a hexagonal crystal structure (HCP).

Another embodiment provides an electronic device including the interconnect structure.

Another embodiment provides an electronic device including a plurality of components, wherein the plurality of components may include a transistor, a capacitor, a diode, a resistor, or a combination thereof; and an interconnect structure disposed at a connection portion between the plurality of components or at a connection portion within each component, wherein the interconnect structure includes a substrate, a metal layer on the substrate, and a capping layer in contact with the metal layer and including a nickel-cobalt alloy, and the nickel-cobalt alloy has a hexagonal crystal structure (HCP).

The electronic device may include a transistor, a capacitor, a diode, or a resistor.

Another embodiment provides an electronic apparatus including the interconnect structure.

The electronic apparatus includes a plurality of units of a memory unit, an arithmetic logic unit, and a control unit, wherein the plurality of units may include each independently a plurality of components, wherein the plurality of components may a transistor, a capacitor, a diode, a resistor, or a combination thereof,
wherein an interconnect structure is disposed at a connection portion between the plurality of units or at a connection portion within each of units,

The interconnect structure may prevent oxidation of the metal wiring while reducing the increase in resistance due to a decrease in the line width or thickness of the metal wiring.

### BRIEF DESCRIPTION OF THE DRAWINGS

FIGS. 1 to 4 are cross-sectional views of interconnect structures according to embodiments.

FIGS. 5 and 6 are cross-sectional views of electronic devices according to embodiments.

FIG. 7 is a conceptual diagram showing an example of an electronic apparatus according to an embodiment.

FIGS. 8A and 8B are graphs showing the results of X-ray diffraction analysis of the stacked structures according to Example 1 and Comparative Example 1, respectively.

FIG. 9 is a graph showing the results of resistance measurements according to the thicknesses of the stacked structures according to Example 1 and Comparative Examples 1 and 2.

FIG. 10 is a graph showing the results of Secondary Ion Mass Spectrometry (SIMS) analysis for the stacked structures according to Example 2 and Comparative Example 3.

### DETAILED DESCRIPTION

Hereinafter, example embodiments of the present disclosure will be described in detail so that a person skilled in the art would understand the same. This disclosure may, however, be embodied in many different forms and is not construed as limited to the example embodiments set forth herein.

The terminology used herein is used to describe embodiments only, and is not intended to limit the present disclosure. The singular expression includes the plural expression unless the context clearly dictates otherwise.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer, or section from another element, component, region, layer, or section. Thus, “a first element,” “component,” “region,” “layer,” or “section” discussed below could be termed a second element, component, region, layer, or section without departing from the teachings herein. The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. “At least one” is not to be construed as limiting “a” or “an.” “Or” means “and/or.” As used herein, the term “and/or” includes any and all combinations of one or more of the associated listed items.

As used herein, terms such as “comprise,” “comprise,” or “have” are intended to designate the presence of implemented features, numbers, steps, components, or a combination thereof, but not one or more other features, numbers, steps, components, or a combination thereof should be understood as being excluded in advance the existence or possibility of addition.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it may be directly on the other element or intervening elements may also be present. In contrast, when an element is referred to as being “directly on” another element, there are no intervening elements present.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±5%, ±3%, or ±1% of the stated value.

Relative terms, such as “downward,” “lower,” or “bottom,” and “upward,” “upper,” or “top,” may be used herein to describe one element's relationship to another element as illustrated in the drawings. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” may therefore, encompasses both an orientation of “lower” and “upper,” depending on the particular orientation of the figure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Example embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In addition, “layer” herein includes not only a shape formed on the whole surface when viewed from a plan view, but also a shape formed on a partial surface.

The use of the term “the” and similar referential terms may refer to both the singular and the plural. Unless the order of the steps constituting the method is clearly stated or stated to the contrary, these steps may be performed in any appropriate order and are not necessarily limited to the order described.

In addition, terms such as “ . . . unit” and “module” used in the specification refer to a unit that performs at least one function or operation, which may be implemented as hardware or software, or as a combination of hardware and software.

The connections or connection members of lines between components shown in the drawings exemplify functional connections and/or physical or circuit connections, and in actual devices, may be represented as various functional connections, physical connections, or circuit connections.

As used herein, “at least one of A, B or C,” “one of A, B, C, or a combination thereof” and “one of A, B, C, and a combination thereof” refer to each element and any combination (e.g., A; B; C; A and B; A and C; B and C; or A, B, and C).

Herein, “a combination thereof” means a mixture of components, a laminate, a composite, an alloy, a blend, and the like.

Herein, “metal” is interpreted as a concept that includes metals and metalloids (semimetals).

According to an embodiment, an interconnect structure includes a dielectric layer, a metal layer on the dielectric, and a capping layer in contact with the metal layer and including a nickel-cobalt alloy, wherein the nickel-cobalt alloy has a hexagonal crystal structure (HCP).

Hereinafter, an interconnect structure according to an embodiment will be described with reference to the attached drawings.

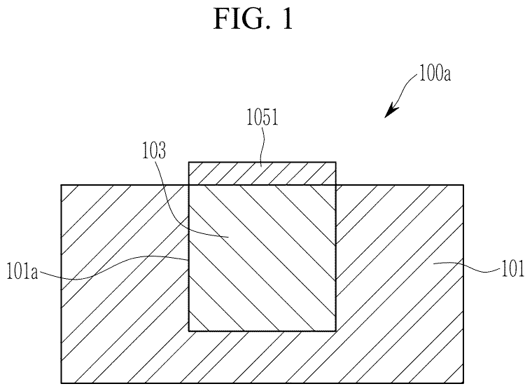

FIG. 1 is a cross-sectional view of an interconnect structure according to an embodiment.

Referring to FIG. 1, an interconnect structure 100a includes a dielectric layer having a trench structure 101a; a metal layer 103 filled in an internal portion of the trench structure 101a; and a capping layer 1051 on the metal layer 103.

Referring to FIG. 1, the interconnect structure 100a includes a metal layer 103 filled inside a trench structure 101a of a substrate 101 and a capping layer 1051 on the metal layer 103.

The interconnect structure 100a may be provided on a substrate (not shown) to constitute an electronic device. For example, the electronic device may include a DRAM or a logic device, and in this case, the interconnect structure 100a may be applied to a BEOL (Back End of Line) structure of the DRAM or the logic device. In addition, the interconnect structure 100a may be applied to various electronic devices.

The substrate may be a semiconductor substrate. For example, the substrate may include a Group IV semiconductor material, a Group III-V semiconductor compound, or a Group II-VI semiconductor compound. That is, the substrate may include a Group IV semiconductor material including at least one of Si, Ge, Sn, and C, a Group III-V compound semiconductor material in which at least one of B, Ga, In, and Al is combined with at least one of N, P, As, and Sb, or a Group II-VI compound semiconductor material in which at least one of Be, Mg, Cd, and Zn is combined with at least one of O, S, Se, and Te. As examples, the substrate may include Si, Ge, SiC, SiGe, SiGeC, Ge alloy, GaAs, InAs, InP, and the like. However, this is an example, and various other semiconductor materials may be used as substrates.

The substrate may include, for example, a Silicon-On-Insulator (SOI) substrate or a Silicon Germanium-On-Insulator (SGOI) substrate. Additionally, the substrate may include a non-doped semiconductor material or a doped semiconductor material.

The substrate may include at least one semiconductor device (not shown). The semiconductor device may include, for example, at least one of a transistor, a capacitor, a diode, and a resistor. However, the present disclosure is not limited thereto.

The dielectric layer 101 is formed on the substrate. This dielectric layer 101 may have a single-layer structure or a multi-layer structure in which a plurality of layers including different materials are stacked. The dielectric layer 101 may be an intermetallic dielectric (IMD) layer. The dielectric layer 101 may include, for example, a low-k dielectric material. For example, the dielectric layer 101 may include a dielectric having a dielectric constant of less than or equal to about 3.6, for example less than or equal to about 3.5, less than or equal to about 3.3, less than or equal to about 3.0, less than or equal to about 2.8, or less than or equal to about 2.7, and greater than or equal to about 0.01, for example greater than or equal to about 0.02, greater than or equal to about 0.03, greater than or equal to about 0.04, or greater than or equal to about 0.05. Here, the low-k material may mean a material with a lower dielectric constant (k) than silicon oxide (SiO₂). As the size of the device decreases, the spacing between metal layers 103 may decrease. Accordingly, the size of the dielectric layer 101 area disposed between the metal layers 103 is reduced, which may cause crosstalk that affects the performance of the device. By using a low-k material in the dielectric layer 101, parasitic capacitance affecting the performance of the device may be reduced, and also fast switching speed and low heat dissipation may be achieved.

In an embodiment, the dielectric layer 101 may include a metal oxide, a carbon-doped metal oxide, a metal carbide, a hydrogenated metal carbide, a metal nitride, a metal oxynitride, or a combination thereof. The dielectric layer 101 may include Al₂O₃, AlN, ZrOₓ (0<x≤2), HfOₓ (0<x≤2), SiO₂, SiCO, SiCN, SiON, SiCOH, AlSiO, BN (boron nitride) or a combination thereof. It will be understood that “SiCO, SiCN, SiON, SiCOH, AlSiO” only indicate the kinds of elements contained in each material, but do not indicate the ratio of each element.

The dielectric layer 101 may include a Group 3A (Group 13) element, a Group 4A (Group 14) element, a Group 4B (Group 4) element, or a combination thereof.

The dielectric layer 101 may be formed on a substrate through a deposition process used in a general semiconductor manufacturing process, such as chemical vapor deposition (CVD), plasma enhanced CVD (PECVD), or spin coating.

The dielectric layer 101 may have a single-layer structure or a multi-layer structure in which multiple layers including dielectrics are stacked.

The trench structure 101a may be formed in the dielectric layer 101 to a predetermined depth. Such a trench structure 101a may be formed, for example, through a photolithography process and an etching process. The trench structure 101a may have a line width of less than or equal to about 10 nm, for example, less than or equal to about 9 nm, less than or equal to about 8 nm, less than or equal to about 7 nm, or less than or equal to about 6 nm and greater than or equal to about 1 nm, and an aspect ratio of greater than or equal to about 3, for example, greater than or equal to about 4, greater than or equal to about 5, or greater than or equal to about 6. The aspect ratio means the depth of the trench structure 101a divided by the width thereof.

The metal layer 103 is present inside the trench structure 101a of the dielectric layer 101. The metal layer 103 forms the wiring structure of the device and may be provided to fill the internal portion of the trench structure 101a.

The metal layer 103 may include a metal, a metal alloy, or a combination thereof.

The metal layer 103 may include a metal such as copper (Cu), ruthenium (Ru), aluminum (Al), cobalt (Co), tungsten (W), molybdenum (Mo), titanium (Ti), tantalum (Ta), nickel (Ni), platinum (Pt), chromium (Cr), rhodium (Rh), iridium (Ir), palladium (Pd), or osmium (Os), an alloy thereof, or a combination thereof.

The metal layer 103 may be formed by chemical vapor deposition (CVD), plasma enhanced chemical vapor deposition (PECVD), physical vapor deposition (PVD), electroplating, chemical solution deposition, or electroless plating using a precursor material of a metal or metal alloy.

In order to achieve high integration of semiconductor devices, the size of semiconductor devices is gradually decreasing, and accordingly, the line width of conductive wiring is also decreasing. As the line width or thickness of the conductive wiring decreases, there is a problem that the resistivity increases significantly due to grain-boundary scattering and/or surface-roughness scattering. This increase in resistivity may cause defects in the conductive wiring by causing electromigration, which may damage the metal layer 103. Here, electromigration refers to the movement of matter by the continuous movement of ions within a conductor resulting from the transfer of momentum between conducting electrons and atomic nuclei within the metal. To prevent or reduce this increase in resistivity, a capping layer 1051 is configured to be on the metal layer 103.

The capping layer 1051 on the upper portion of the metal layer 103 includes a nickel-cobalt alloy, and the nickel-cobalt alloy may have a hexagonal crystal structure (HCP). The nickel-cobalt alloy having the hexagonal crystal structure may suppress an exponential increase in resistance value, reduce or suppress oxidation of the metal layer 103, and improve adhesive strength to the metal layer 103 even when the width of the metal layer 103 becomes smaller compared to nickel-cobalt alloys having other crystal structures.

The nickel-cobalt alloy may include a compound represented by Ni₁₋ₓCoₓ (0<x<1). In the nickel-cobalt alloy, x may be in a range of about 0.5 to about 0.99, for example, about 0.6 to about 0.95. Within the above range, x may be in a range of greater than or equal to about 0.5, for example, greater than or equal to about 0.55, greater than or equal to about 0.6, greater than or equal to about 0.65, about 0.70, and may be less than or equal to about 0.99, such as less than or equal to about 0.5, less than or equal to about 0.9, less than or equal to about 0.85, or less than or equal to about 0.80. Within the above range, the desired crystal structure of the nickel-cobalt alloy may be obtained, the increase in resistance due to the decrease in the line width of the metal layer 103 may be alleviated, and sufficiently low oxidation resistance may be obtained.

The nickel-cobalt alloy may be a ternary alloy or a higher alloy by further including a metal such as Ru, Hf, Zr, Gd, Nb, V, or a combination thereof.

The capping layer 1051 may be formed of a plurality of layers including nickel-cobalt alloys having different alloy compositions. In an embodiment, the capping layer 1051 includes a plurality of layers, a first layer in contact with the metal layer 103, and a second layer formed on the first layer, and the cobalt content of the nickel-cobalt alloy of the first layer may be higher than the cobalt content of the nickel-cobalt alloy of the second layer. For example, a difference between the cobalt content of the nickel-cobalt alloy of the first layer and the cobalt content of the nickel-cobalt alloy of the second layer may be greater than or equal to about 10 at %, for example, greater than or equal to about 12 at %, greater than or equal to about 13 at %, about 14 at %, greater than or equal to about 15 at %, greater than or equal to about 16 at %, greater than or equal to about 17 at %, a greater than or equal to about 18 at %, greater than or equal to about 19 at %, or greater than or equal to about 20 at % and may be less than or equal to about 60 at % or less than or equal to about 50 at %. Within the above range, the crystal structure of the nickel-cobalt alloy may be easily controlled to have a hexagonal crystal structure.

A lattice mismatching ratio of the metal, metal alloy, or combination thereof of the metal layer 103 and the nickel-cobalt alloy of the capping layer 1051 may be less than or equal to about 5%, for example, less than or equal to about 4%, less than or equal to about 3%, less than or equal to about 2%, or less than or equal to about 1%. When the lattice mismatch ratio is within the above range, the adhesion between the metal layer 103 and the capping layer 1051 may be improved, and electromigration of the metal layer 103 may be suppressed or reduced.

The nickel-cobalt alloy may have a cohesive energy of greater than or equal to about 4.5 eV/atom, for example greater than or equal to about 5.0 eV/atom, greater than or equal to about 5.5 eV/atom, and greater than or equal to about 10 eV/atom. When the cohesive energy is within the above range, the adhesive strength with the metal layer 103 may be improved. The cohesive energy may be obtained by an ab initio calculation method based on density functional theory (DFT).

The capping layer 1051 may have a thickness of less than or equal to about 3 nm, for example, less than or equal to about 2.5 nm, less than or equal to about 2.0 nm, less than or equal to about 1.5 nm, or less than or equal to about 1.0 nm, and greater than or equal to about 0.01 nm, for example, greater than or equal to about 0.02 nm, greater than or equal to about 0.03 nm, greater than or equal to about 0.04 nm, or greater than or equal to about 0.05 nm. Within the above range, it is possible to prevent or reduce the increase in resistance due to a decrease in the line width or thickness of the metal layer 103 and secure oxidation resistance.

The capping layer 1051 may be formed using precursor materials of nickel and cobalt through chemical vapor deposition (CVD), plasma enhanced chemical vapor deposition (PECVD), physical vapor deposition (PVD), electroplating, chemical solution deposition, or electroless plating.

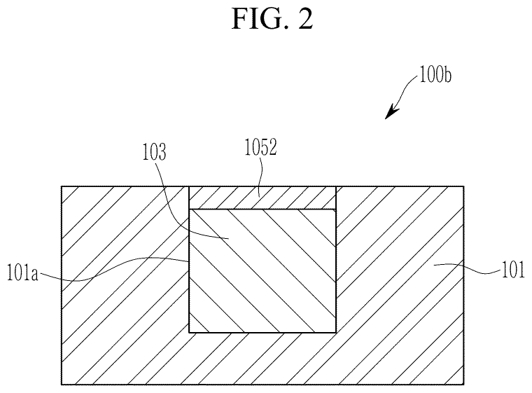

The metal layer and capping layer may be present inside the trench structure. This structure is illustrated in FIG. 2. FIG. 2 is a cross-sectional view of an interconnect structure according to another embodiment.

Referring to FIG. 2, the interconnect structure 100b includes a dielectric layer 101 having a trench structure 101a; a metal layer 103 filled inside the trench structure 101a and a capping layer 1052 formed on the metal layer 103. Since the capping layer 1052 has the same configuration as the interconnect structure 100a illustrated in FIG. 1 except that it exists inside the trench structure 101a, a duplicate description is omitted.

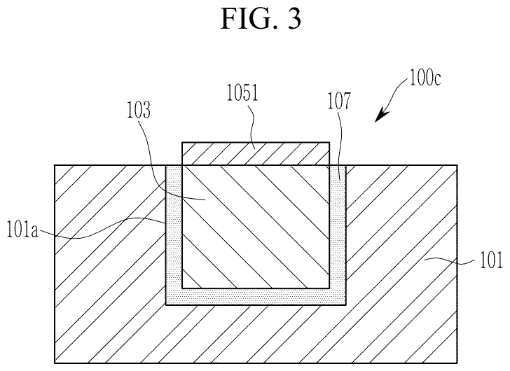

A barrier layer may be further included between the dielectric layer 101 and the metal layer 103. A structure in which a barrier layer is additionally included in the interconnect structure of FIG. 1 is illustrated in FIG. 3. FIG. 3 is a cross-sectional view of an interconnect structure according to an embodiment.

Referring to FIG. 3, the interconnect structure 100c includes a dielectric layer 101 having a trench structure 101a; a metal layer 103 filled within the trench structure 101a; a capping layer 1051 on the metal layer 103; and a barrier layer 107 between the dielectric layer 101 and the metal layer 103.

Since it has the same configuration as the interconnect structure 100a illustrated in FIG. 1 except that it further includes the barrier layer 107, a duplicate description is omitted.

In FIG. 3, a barrier layer 107 is formed on both sides and the lower surface of the trench structure 101a of the dielectric layer 101, but the barrier layer 107 may be formed on either side or the lower surface.

The barrier layer 107 may prevent the material of the metal layer 103 from diffusing into the dielectric layer 101. The barrier layer 107 may have a multi-layer structure in which a plurality of layers including different materials are stacked. For example, the barrier layer 107 may include a first barrier layer in contact with the metal layer 103 and a second barrier layer in contact with the dielectric layer 101, and the first barrier layer may include a metal or an alloy of metals and the second barrier layer may include a metal nitride or a metal oxide.

The barrier layer 107 may include a metal, a metal alloy, a metal oxide, a metal nitride, or a combination thereof.

The metal that may be used in the barrier layer 107 may be magnesium (Mg), aluminum (Al), scandium (Sc), titanium (Ti), vanadium (V), chromium (Cr), manganese (Mn), nickel (Ni), zinc (Zn), gallium (Ga), zirconium (Zr), niobium (Nb), molybdenum (Mo), lead (Pd), silver (Ag), cadmium (Cd), indium (In), tin (Sn), lanthanum (La), hafnium (Hf), tantalum (Ta), tungsten (W), iridium (Ir), platinum (Pt), gold (Au), bismuth (Bi), ruthenium (Ru), or a combination thereof. The metal alloy of the barrier layer 107 may include RuTa, IrTa, and the like.

The metal oxide of the barrier layer 107 may include a compound represented by Chemical Formula 1:

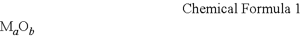

wherein in Chemical Formula 1,
M may be at least one of Mn, Al, Ti, Zr, Hf, Mg, Si, Ge, Y, Lu, La, Ta, and Sr, 0<a≤2, and 0<b≤3.

Examples of the metal oxide may include MnO, AlO_{z} (0<z≤3/2), TaO_{z} (0<z≤5/2), TiO₂, ZrO₂, HfO₂, MgO, SiO₂, GeO₂, Y₂O₃, Lu₂O₃, La₂O₃, SrO, and the like.

The metal nitride of the barrier layer 107 may include tantalum nitride (TaN), titanium nitride (TiN), ruthenium nitride (RuN), tungsten nitride (WN), aluminum nitride (AlN), IrTaN, TiSiN, and the like.

A liner layer (not shown) may be further disposed between the metal layer 103 and the dielectric layer 101 or between the metal layer 103 and the barrier layer 107 to improve adhesive strength (adhesion) between the metal layer 103 and the adjacent layer.

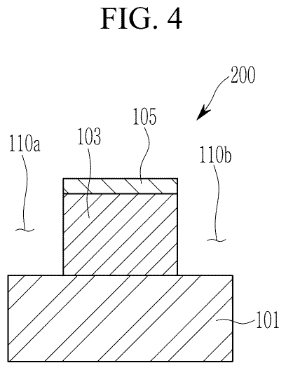

In a wiring structure where the upper surface is a flat substrate, there may be empty space on both sides of the metal layer. This structure is illustrated in FIG. 4. FIG. 4 is a cross-sectional view of an interconnect structure according to another embodiment.

Referring to FIG. 4, the interconnect structure 200 has a multi-layer structure in which a metal layer 103 and a capping layer 105 are stacked on, e.g., disposed on a dielectric layer 101, and empty spaces 110a and 110b exist on both sides of the multi-layer structure. In FIG. 4, the empty spaces 110a and 110b may be filled with air, etc., and if the empty spaces 110a and 110b are an air gap filled with air, the air gap itself may act as a dielectric.

A barrier layer may be disposed on at least one of the lower surface and both sides of the metal layer 103 illustrated in FIG. 4.

The interconnect structure may be manufactured by a process which includes forming a metal layer on a substrate, and depositing a nickel-cobalt alloy on the metal layer to form a capping layer. The nickel-cobalt alloy has a hexagonal crystal structure (HCP). The description of the substrate, metal layer, and capping layer and the method of forming them are as described above.

The interconnect structure 200 may alleviate an increase in electrical resistance due to a decrease in the line width or thickness of a wiring due to high integration of semiconductor devices and reduce or prevent defects due to electromigration caused by an increase in electrical resistance within the interconnect structure.

According to another embodiment, an electronic device includes: a plurality of components, wherein the plurality of components may include at least one of a transistor, a capacitor, a diode, or a resistor, and the interconnect structure is disposed at a connection portion between the plurality of components or at a connection portion within each component.

The aforementioned interconnect structures 100a, 100b, 100c, and 200 may reduce the increase in resistance due to a decrease in the line width of the interconnect structure by including the metal layer 103 and the capping layer including a nickel-cobalt alloy having a specific crystal structure on the metal layer 103.

The aforementioned interconnect structures 100a, 100b, 100c, and 200 may constitute electronic devices. For example, the electronic device may include a semiconductor device, in which case the interconnect structures 100a, 100b, 100c, and 200 may be applied to a Back End of Line (BEOL) structure of the semiconductor device, and the like. The semiconductor device may include at least one of a transistor, a capacitor, a diode, or a resistor. For example, the transistor may have various structures, including a FinFET, a GAAFET, an MBCFET, a CFET, or a VFET, but is not limited thereto. For example, the transistor may include a two-dimensional material as the active material and may be a complementary field effect transistor (C-FET), a multi bridge channel field effect transistor (MBC-FET), or a carbon nanotube field effect transistor (CNT-FET), but is not limited thereto. In addition, the interconnect structures 100a, 100b, 100c, and 200 may be applied to various electronic devices.

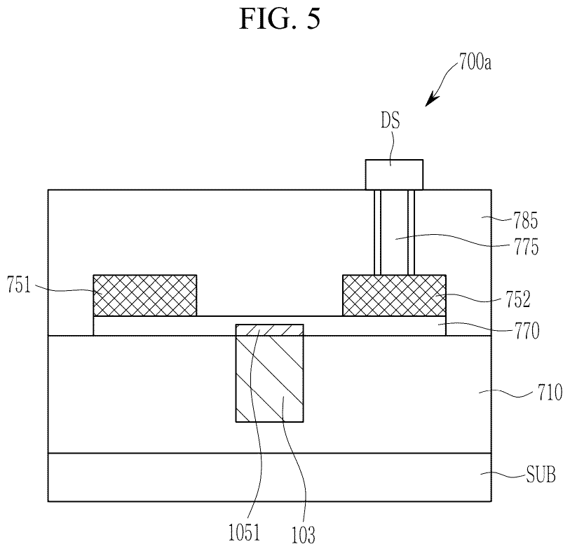

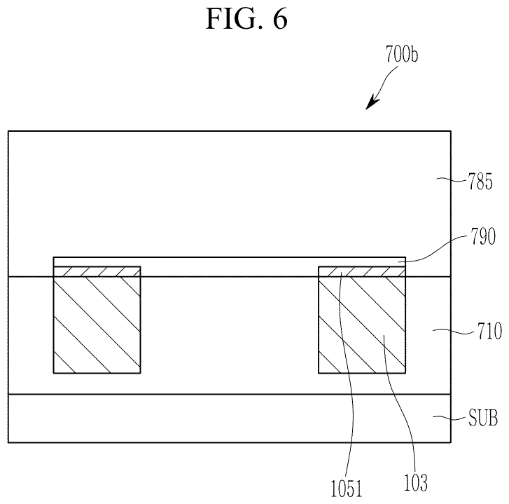

Hereinafter, an electronic device including the aforementioned interconnect structures will be described with reference to FIGS. 5 and 6.

FIGS. 5 and 6 are cross-sectional views of electronic devices according to some embodiments.

Referring to FIG. 5, in one implementation, the electronic device 700a may be formed of a transistor connected to a data storage DS. The electronic device 700a may include a substrate SUB, an oxide dielectric layer 710, a metal layer 103 present within a trench of the oxide dielectric layer 710, and a capping layer 1051 present on the metal layer 103. The metal layer 103 and capping layer 1051 may have the same structure as that shown in FIG. 1. In FIG. 5, the interconnect structure 100a may be replaced with any of the structures illustrated in FIGS. 2 to 4.

The gate insulating layer 770 is formed on the oxide dielectric layer 710. The source electrode 751 and the drain electrode 752 are arranged spaced apart from each other on the gate insulating layer 770. The metal layer 103 may be configured to operate as a gate electrode of an electronic device 770a.

The electronic device 700a may further include an insulating layer 785, such as including silicon oxide, covering the source electrode 751, the gate insulating layer 770, and the drain electrode 752, and a data storage DS (e.g., a capacitor) may be on the insulating layer 785. Contact 775 including an electrically conductive material such as a metal or a metal alloy may connect data storage DS and drain electrode 752.

Referring to FIG. 6, in an embodiment, the electronic device 700b different from the electronic device 700a shown in FIG. 5 in that the gate insulating layer 770, the contact 775, the source electrode 751, the drain electrode 752, and the data storage DS are omitted. Additionally, the oxide dielectric layer 710 includes two trenches spaced apart from each other, and each of the trenches is formed in the same structure as the interconnect structure in FIG. 1. That is, each of the trenches may include a metal layer 103 formed therein and a capping layer 1051 formed on the metal layer 103.

The upper conductive layer 790 is formed on the oxide dielectric layer 710 and contacts the upper surface of the metal layer 103 in each interconnect structure, so that the interconnect structures may be electrically connected to each other. The upper conductive layer 790 may include a conductive material such as a metal, a metal alloy, or a doped semiconductor. In FIG. 6, the interconnect structure 100a may be replaced with any one of the interconnect structures illustrated in FIGS. 2 to 4.

The aforementioned interconnect structures may be included in various electronic apparatuses.

The electronic apparatus includes: a plurality of units of a memory unit, an arithmetic logic unit, and a control unit, the plurality of units each independently including a plurality of components, the plurality of components including a transistor, a capacitor, a diode, a resistor, or a combination thereof, and an interconnect structure disposed at a connection portion between the plurality of components or at a connection portion within each component.

The electronic apparatuses may include mobile devices, computers, laptops, tablet PCs, smart watches, sensors, digital cameras, e-books, network devices, vehicle navigation systems, Internet of Things (IoT) devices, Internet of Everything (IoE) devices, drones, door locks, safes, automated teller machines (ATMs), security devices, medical devices, or automotive electrical components, but are not limited thereto.

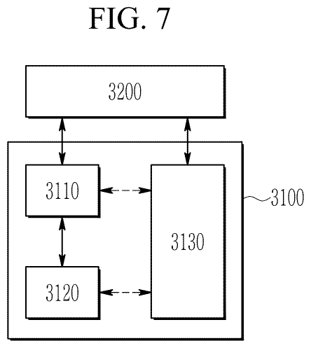

FIG. 7 is a conceptual diagram showing an example of an electronic apparatus according to an embodiment.

Referring to FIG. 7, an electronic apparatus 3100 according to an embodiment may include a memory unit 3110, an arithmetic logic unit 3120, and a control unit 3130, which may be electrically connected. For example, the memory unit 3110, the arithmetic logic unit 3120, and the control unit 3130 may be implemented as a single integrated circuit device (semiconductor chip), and may be monolithically integrated on a single substrate to be implemented as a single integrated circuit device (semiconductor chip). The memory unit 3110, the arithmetic logic unit 3120, and the control unit 3130 may each independently include a transistor, a capacitor, a diode, a resistor, or a combination thereof. The electronic apparatus 3100 may be connected to one or more input/output devices 3200.

Hereinafter, the embodiments are illustrated in more detail with reference to examples. However, the following examples are for illustrative purposes only and do not limit the scope of the rights.

### Example 1: Manufacturing of Stacked Structure

A film is formed by depositing a nickel-cobalt alloy (Ni_{0.4}Co_{0.6}) to have each thickness of 5 nm, 10 nm, 15 nm, 20 nm, and 25 nm on a 430 micrometers (μm)-thick sapphire c-plane (0001) at 250° C. in a sputtering method to manufacture a stacked structure.

### Comparative Example 1: Manufacturing of Stacked Structure

A film is formed by depositing a nickel-cobalt alloy (Ni_{0.4}Co_{0.6}) to have each thickness of 5 nm, 10 nm, 15 nm, 20 nm, and 25 nm on a 430 μm-thick sapphire a-plane (11-20) at 250° C. in the sputtering method to manufacture a stacked structure.

### Comparative Example 2: Manufacturing of Stacked Structure

A film is formed by depositing cobalt to have each thickness of 5 nm, 10 nm, 15 nm, 20 nm, and 25 nm on a sapphire c-plane (0001) at 250° C. in the sputtering method to manufacture a stacked structure.

### Example 2: Manufacturing of Stacked Structure

A film is formed by depositing a nickel-cobalt alloy (Ni_{0.4}Co_{0.6}) to have a thickness of 20 nm on a SiO₂/Si (100 nm/0.725 millimeters (mm) dielectric layer at 250° C. in a sputtering method to manufacture a stacked structure.

### Comparative Example 3: Manufacturing of Stacked Structure

A film is formed by depositing cobalt to have a thickness of 20 nm on a SiO₂/Si (100 nm/0.725 mm) dielectric layer at 250° C. in the sputtering method to manufacture a stacked structure.

### Evaluation 1: Crystal Structure of Stacked Structure

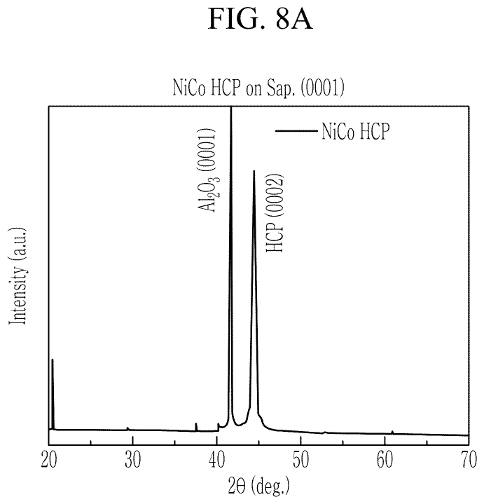

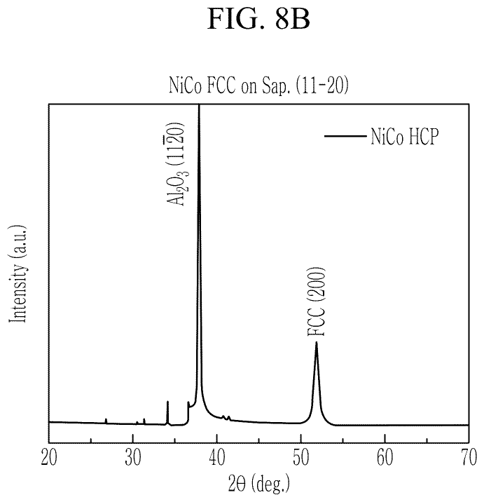

The stacked structures with a film thickness of 20 nm according to Example 1 and Comparative Example 1 are subjected to X-ray diffraction analysis (light source: Cu Kα, 2θ=20° to 70°), and the results are respectively shown in FIGS. 8A and 8B. FIGS. 8A and 8B are graphs showing the X-ray diffraction analysis results of the stacked structures according to Example 1 and Comparative Example 1. Referring to FIGS. 8A and 8B, the nickel-cobalt alloy of the stacked structure according to Example 1 has a hexagonal crystal structure (HCP), but the nickel-cobalt alloy of the stacked structure of Comparative Example 1 has a face centered cubic crystal structure (FCC).

### Evaluation 2: Resistance Measurement According to Thickness of Stacked Structure

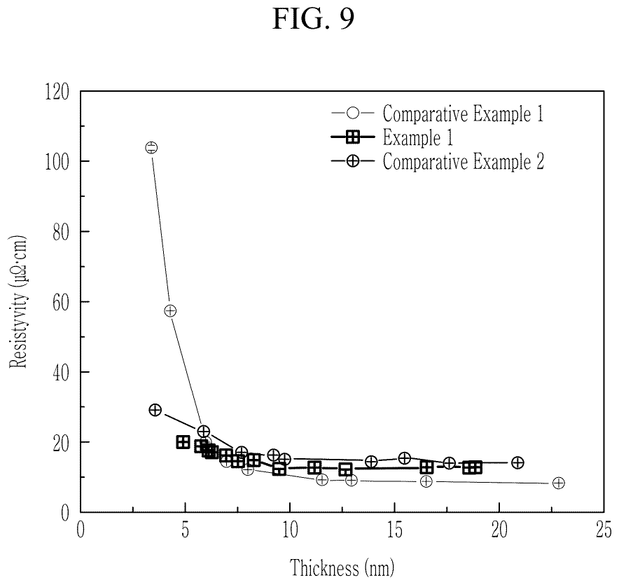

The stacked structures of Example 1 and Comparative Examples 1 and 2 are measured with respect to resistance according to a thickness, and the results are shown in FIG. 9. FIG. 9 is a graph showing the resistance measurements according to the thicknesses of the stacked structures according to Example 1 and Comparative Examples 1 and 2. The resistance according to a film thickness is measured in a four-point probe method. Referring to FIG. 9, the stacked structure of Example 1 shows a smaller increase in resistance at a thickness of less than 10 nm than those of Comparative Examples 1 and 2. In other words, the stacked structure of Example 1 has a smaller effect of the resistance increase according to size decrease than those of Comparative Examples 1 and 2.

### Evaluation 3: Oxidation Resistance of Stacked Structure

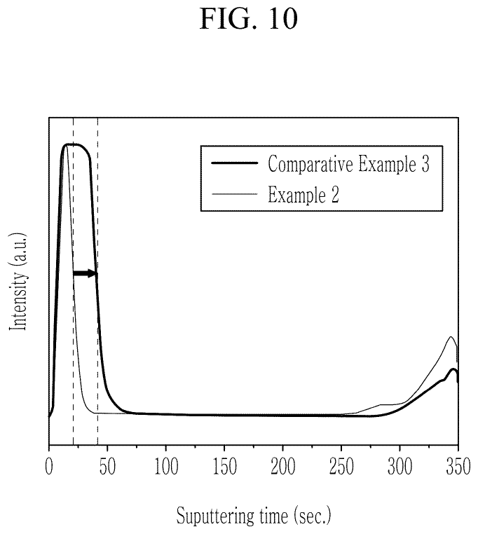

The stacked structures of Example 2 and Comparative Example 3 are subjected to Secondary Ion Mass Spectrometry (SIMS) analysis to check whether or not an oxide layer is formed, and the results are shown in FIG. 10. The SIMS analysis is performed by using a SIMS analysis equipment (model name: ToF-SIMS, manufacturer: ION-TOF GmbH, Muenster). FIG. 10 is a graph showing the Secondary Ion Mass Spectrometry (SIMS) analysis results of the stacked structures according to Example 2 and Comparative Example 3. In the graph of FIG. 10, “0” of a horizontal axis means the surface of the stacked structures. The profile of FIG. 10 shows the analysis results of CoO⁻, wherein CoO⁻ is less detected in the stacked structure of Example 2 than in that of Comparative Example 3. Accordingly, the stacked structure of Example 2 is confirmed to exhibit excellent oxidation resistance than that of Comparative Example 3.

### Evaluation 4: Cohesive Energy of Nickel-Cobalt Alloy

The nickel-cobalt alloys are measured with respect to cohesive energy according to a cobalt content in an ab initio method based on density functional theory (DFT), and the results are shown in Table 1.

TABLE 1

| Cobalt content of nickel- | Crystal structure of nickel- | Cohesive energy |
|---|---|---|
| cobalt alloy (at %) | cobalt alloy | (eV/atom) |
| 25 | HCP | 5.11 |
| 50 | HCP | 5.12 |
| 75 | HCP | 5.13 |

Referring to Table 1, the nickel-cobalt alloy is confirmed to have excellent cohesive energy within all the cobalt contents ranging from 25 to 75 at %. Herein, high cohesive energy may reduce electromigration of a nickel-cobalt alloy and its adjacent layer, thereby improving reliability of a device.

While the embodiments of the present disclosure have been described in detail, it is to be understood that the disclosure is not limited to the disclosed embodiments, but on the contrary, is intended to cover various modifications and equivalent arrangements included within the spirit and scope of the appended claims.

What is claimed is:

1. An interconnect structure, comprising
a substrate,
a metal layer on the substrate, and
a capping layer in contact with the metal layer and including a nickel-cobalt alloy,
wherein the nickel-cobalt alloy has a hexagonal crystal structure.

2. The interconnect structure of claim 1, wherein
the metal layer comprises a metal, a metal alloy, or a combination thereof.

3. The interconnect structure of claim 2, wherein
the metal of the metal layer comprises a transition metal, a Group 3A (Group 13) metal, or a combination thereof.

4. The interconnect structure of claim 1, wherein
the metal layer comprises copper, ruthenium, aluminum, cobalt, tungsten, molybdenum, titanium, tantalum, nickel, platinum, chromium, rhodium, iridium, palladium, or osmium, an alloy thereof, or a combination thereof.

5. The interconnect structure of claim 1, wherein
the nickel-cobalt alloy comprises a compound represented by Ni₁₋ₓCoₓ, wherein 0<x<1.

6. The interconnect structure of claim 5, wherein
x in the nickel-cobalt alloy is in a range of about 0.5 to about 0.99.

7. The interconnect structure of claim 5, wherein
x in the nickel-cobalt alloy is in a range of about 0.6 to about 0.95.

8. The interconnect structure of claim 1, wherein
the nickel-cobalt alloy further comprises one of ruthenium, hafnium, zirconium, gadolinium, niobium, vanadium, or a combination thereof.

9. The interconnect structure of claim 2, wherein
a lattice mismatching ratio of a metal, a metal alloy, or a combination thereof of the metal layer and the nickel-cobalt alloy of the capping layer is less than or equal to about 5%.

10. The interconnect structure of claim 1, wherein
the capping layer comprises a plurality of layers, a first layer in contact with the metal layer, and a second layer formed on the first layer, wherein a cobalt content of the nickel-cobalt alloy of the first layer is higher than a cobalt content of the nickel-cobalt alloy of the second layer.

11. The interconnect structure of claim 10, wherein
a difference between the cobalt content of the nickel-cobalt alloy of the first layer and the cobalt content of the nickel-cobalt alloy of the second layer is greater than or equal to about 10 atomic percentage.

12. The interconnect structure of claim 1, wherein
the capping layer has a thickness of less than or equal to about 10 nanometers.

13. The interconnect structure of claim 1, wherein
the substrate comprises a dielectric layer having a trench structure, and
the interconnect structure comprises the metal layer filling an internal portion of the trench structure and the capping layer on the metal layer.

14. The interconnect structure of claim 1, wherein
the trench structure has a width of less than or equal to about 10 nanometers and an aspect ratio of greater than or equal to about 3.

15. The interconnect structure of claim 13, wherein
a barrier layer is further included on at least one surface of the internal portion of the trench structure.

16. The interconnect structure of claim 15, wherein
the barrier layer comprises a metal, a metal alloy, a metal oxide, a metal nitride, or a combination thereof.

17. The interconnect structure of claim 1, wherein
a multi-layer structure in which the metal layer and the capping layer are stacked on the substrate, and empty spaces are present on both sides of the multi-layer structure.

18. An electronic device, comprising
a plurality of components,
wherein the plurality of components comprises a transistor, a capacitor, a diode, a resistor, or a combination thereof, and an interconnect structure disposed at a connection portion between the plurality of components or at a connection portion within each component,
wherein the interconnect structure comprises
a substrate,
a metal layer on the substrate, and
a capping layer in contact with the metal layer and including a nickel-cobalt alloy,
wherein the nickel-cobalt alloy has a hexagonal crystal structure.

19. The electronic device of claim 18, wherein
the nickel-cobalt alloy comprises a compound represented by Ni₁₋ₓCoₓ, wherein 0<x<1.

20. An electronic device, comprising
a plurality of units of a memory unit, an arithmetic logic unit, and a control unit,
wherein the plurality of units comprises a transistor, a capacitor, a diode, a resistor, or a combination thereof,
wherein an interconnect structure is disposed at a connection portion between the plurality of units or at a connection portion within each unit,
the interconnect structure comprises
a substrate,
a metal layer on the substrate, and
a capping layer in contact with the metal layer and including a nickel-cobalt alloy, and
the nickel-cobalt alloy has a hexagonal crystal structure.
